(19) United States
(12) Patent Application Publication
(10) Pub. No.: US 2025/0266343 A1
(43) Pub. Date: Aug. 21, 2025

(54) PACKAGE STRUCTURE AND METHOD OF FORMING THE SAME

(71) Applicant: Taiwan Semiconductor Manufacturing Company, Ltd., Hsinchu (TW)

(72) Inventors: Wei-Yu Chen, Hsinchu City (TW); Hao-Yi Tsai, Hsinchu City (TW); Shang-Yun Hou, Hsinchu (TW); Yen-Ming Chen, Hsin-Chu County (TW); Tsung-Ding Wang, Tainan (TW); Hao-Cheng Hou, Hsinchu City (TW)

(73) Assignee: Taiwan Semiconductor Manufacturing Company, Ltd., Hsinchu (TW)

(21) Appl. No.: 18/443,323

(22) Filed: Feb. 16, 2024

(51) Int. Cl. H01L 23/498; H01L 23/00; H01L 23/31; H01L 23/522; H01L 25/00; H01L 25/16

(52) U.S. Cl. CPC H01L 23/49838; H01L 23/3128; H01L 23/49822; H01L 23/5227; H01L 25/16; H01L 25/50; H01L 24/16; H01L 24/32; H01L 24/73; H01L 2224/16227; H01L 2224/32227; H01L 2224/73204; H01L 2924/181

(57) ABSTRACT

Provided are a package structure and a method of forming the same. The package structure includes an interposer at least including a first die sandwiched between a first redistribution layer (RDL) structure and a second RDL structure. The first die includes: a device layer disposed on a substrate; an inductor device disposed on the device layer; an internal RDL structure disposed on the inductor device; a plurality of conductive connectors disposed on the internal RDL structure; and an inductor contact disposed aside the inductor device and electrically connecting the internal RDL structure and inductor device. The internal RDL structure is configured to redistribute an electrical signal from the inductor contact to the plurality of conductive connectors, thereby preventing the electromigration (EM) failure.

### BACKGROUND

The semiconductor industry has experienced rapid growth due to continuous improvements in the integration density of a variety of circuit components (e.g., transistors, diodes, resistors, capacitors, etc.). For the most part, this improvement in integration density has come from repeated reductions in minimum feature size, which allows more components to be integrated into a given area. Accordingly, many types of packages have been developed to suit to customized requirements of integrated circuits. Power networks are also built inside the packages to provide power to the device dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 7, 8, 9, 10, 11, 12A, 13, and 14 illustrate cross-sectional views of intermediate stages in the formation of a package structure in accordance with some embodiments.

FIGS. 4A, 4B, and 4C illustrate cross-sectional views of a first die with an inductor device in accordance with various embodiments.

FIGS. 5A, 5B, and 5C illustrates plan views of the conductive connectors of FIGS. 4A, 4B, and 4C, respectively.

FIG. 6 illustrates a cross-sectional view of a second die in accordance with some embodiments.

FIG. 12B illustrates a cross-sectional view of an integrated circuit die in accordance with some embodiments.

FIG. 15 illustrates a cross-sectional view of a package structure in accordance with some alternative embodiments.

FIG. 16A and FIG. 16B illustrate cross-sectional views of a die stack structure with an inductor device in accordance with various embodiments.

FIG. 17 illustrates a cross-sectional view of a package structure in accordance with some other embodiments.

FIG. 18 illustrates a cross-sectional view of a package component with an inductor device in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with some embodiments, an all-in-one solution to efficiently integrate the local silicon interconnect (LSI) die, the active integrated voltage regulator (IVR) die, and/or the active system-on-a-chip (SoC) die in an interposer of the package structure is provided. Compared with the conventional IVR die mounted on the package substrate, the active IVR die with the power management integrated circuit (PMIC) and the inductor device is embedded in the interposer which is closer to the overlying package components than the conventional IVR die. In such embodiment, the shortened distance can prevent the unnecessary power loss and parasitic capacitance, so that the electrical signal has better voltage regulation before this electrical signal is transmitted to the overlying package components. In addition, the LSI die, the active IVR die, and/or the active SoC die are stacked in one package component and the package component is integrated in the interposer. In this case, the package component in the interposer communicates the overlying package component (e.g., SoC and/or HBM) through the vertical conductive path rather than through the lateral RDL structure. As a result, the transmission speed between dies will become faster, thereby improving the performance of the package structure.

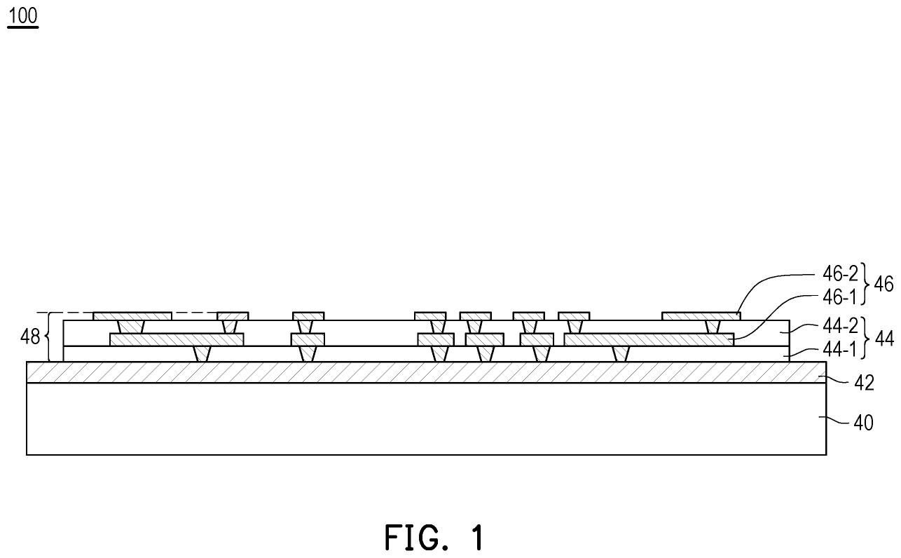

FIG. 1 through FIG. 14 illustrate the intermediate stages in the formation of a package structure 100 including a first die with an inductor device in accordance with some embodiments. FIG. 1 illustrates the formation of release film 42 on carrier 40. The carrier 40 may be a glass carrier, a silicon wafer, an organic carrier, or the like. The carrier 40 may have a round top-view shape in accordance with some embodiments. The release film 42 may be formed of a polymer-based material and/or an epoxy-based thermal-release material (such as a Light-To-Heat-Conversion (LTHC) material), which is capable of being decomposed under radiation such as a laser beam, so that the carrier 40 may be de-bonded from the overlying structures that will be formed in subsequent processes. In accordance with some embodiments, the release film 42 is applied on the carrier 40 through coating.

A first redistribution layer (RDL) structure 48, which includes a plurality of dielectric layers 44 and a plurality of Redistribution Lines (RDLs) 46, is formed over the release film 42. As shown in FIG. 1, a first dielectric layer 44-1 is formed on the release film 42. In accordance with some embodiments, the dielectric layer 44-1 is formed of or comprises an organic material, which may be a polymer. The organic material may also be a photo-sensitive material. For example, the dielectric layer 44-1 may be formed of or comprises polyimide, PBO, BCB, or the like. The dielectric layer 44-1 may be formed using a process such as lamination, coating, (e.g., spin-coating), chemical vapor deposition (CVD), or the like.

A first plurality of RDLs 46 (denoted as 46-1) are formed on dielectric layer 44-1. The formation of RDLs 46-1 may include patterning dielectric layer 44-1 to form via openings, forming a metal seed layer (not shown) over dielectric layer 44-1 and extending into the via openings, forming a patterned plating mask (not shown) such as a photoresist over the metal seed layer, and then performing a metal plating process to deposit a metallic material (e.g., copper, or the like) on the exposed metal seed layer. The patterned plating mask and the portions of the metal seed layer covered by the patterned plating mask are then removed, leaving RDLs 46-1 as shown in FIG. 1. In accordance with some embodiments, the metal seed layer includes a titanium layer and a copper layer over the titanium layer. The metal seed layer may be formed using, for example, PVD or a like process. The plating process may be performed using, for example, an electrochemical plating process or an electro-less plating process.

FIG. 1 further illustrates the formation of additional dielectric layer(s) 44-2 and additional RDLs (such as RDLs 46-2), for example. Throughout the description, dielectric layers 44-1 and 44-2 are individually and collectively referred to as dielectric layers 44, and RDLs 46-1 and 46-2 are individually and collectively referred to as RDLs 46. In accordance with some embodiments, dielectric layer 44-2 is first formed on RDLs 46-1. The bottom surface of dielectric layer 44-2 is in contact with the top surfaces of RDLs 46-1 and dielectric layer 44-1. Dielectric layer 44-2 may be formed of or comprise an organic dielectric material, which may be a polymer. For example, dielectric layer 44-2 may comprise a photo-sensitive material such as PBO, polyimide, BCB, or the like. Dielectric layer 44-2 is then patterned to form via openings (occupied by the via portions of RDLs 46-2) therein. Hence, some portions of RDLs 46-1 are exposed through the openings in dielectric layer 44-2.

Next, RDLs 46-2 are formed on dielectric layer 44-2 to connect the RDLs 46-1. The RDLs 46-2 include via portions (also referred to as vias) extending into the openings in the dielectric layer 44-2, and trace portions (metal line portions, or RDL lines) over the dielectric layer 44-2. The formation of the RDLs 46-2 may be similar to the formation of the RDLs 46-1. Each of the vias may have a tapered profile, with the upper portions being wider than the corresponding lower portions.

After the formation of the RDLs 46-2, there may be more dielectric layers and the corresponding RDLs formed, with the upper RDLs over and landing on the respective lower RDLs. The materials of the more dielectric layers may be selected from the same group (or different groups) of candidate materials as the dielectric layers 44-1 and 44-2, which candidate materials may include a polymer such as polyimide, PBO, BCB, or the like. The dielectric layers 44 and the RDLs 46 collectively form the first RDL structure 48.

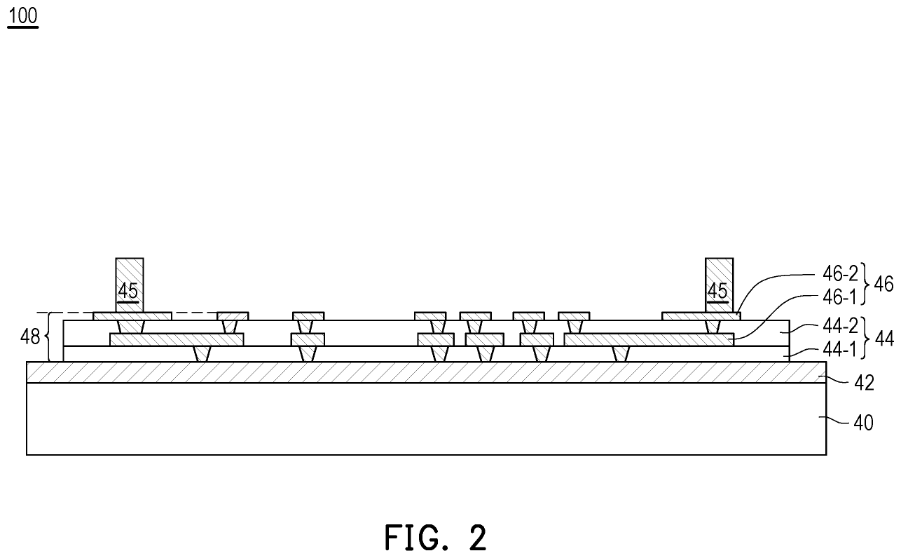

Referring to FIG. 2, after the formation of the first RDL structure 48, conductive vias 45 may be formed over the first RDL structure 48. The formation of the conductive vias 45 may include depositing a metal seed layer over RDLs 46, and forming a patterned plating mask, through which some portions of the metal seed layer are exposed. In accordance with some embodiments, the metal seed layer may include a copper layer, a titanium layer and a copper layer over the titanium layer, or the like. A plating process is then performed to plate a metallic material (e.g., copper, or the like) into the openings in the plating mask. The plating process may be performed using, for example, an electrochemical plating process or an electro-less plating process. The plating mask is then removed, followed by the etching of the exposed portions of the metal seed layer to form the conductive vias 45. The conductive vias 45 are formed to be electrically connected to the RDLs 46.

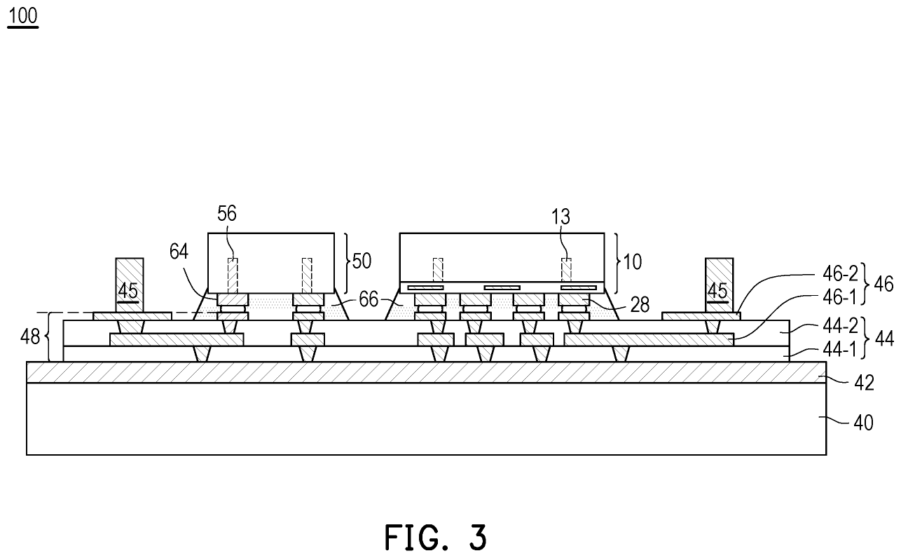

Referring to FIG. 3, a first die 10 and a second die 50 are bonded onto the RDLs 46. In some embodiments, the first die 10 is different from the second die 20. For example, the first die 10 is an active device die, an integrated voltage regulator (IVR) die, and/or the like, while the second die 50 is a passive device die, an interconnect die, a bridge die, and/or the like. In detail, the second die 50 may include an Independent Passive Device (IPD) die including a capacitor therein, an IPD die including a resistor therein, an interconnect die for bridging two device dies, and/or the like.

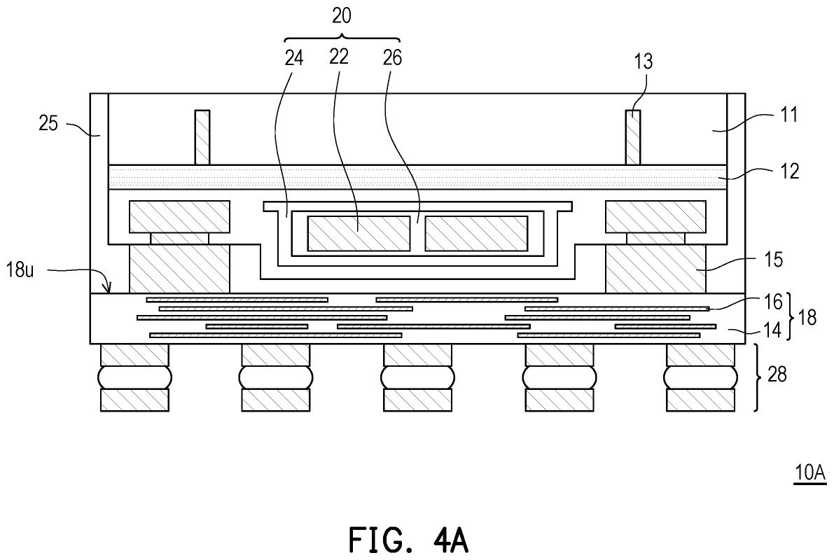

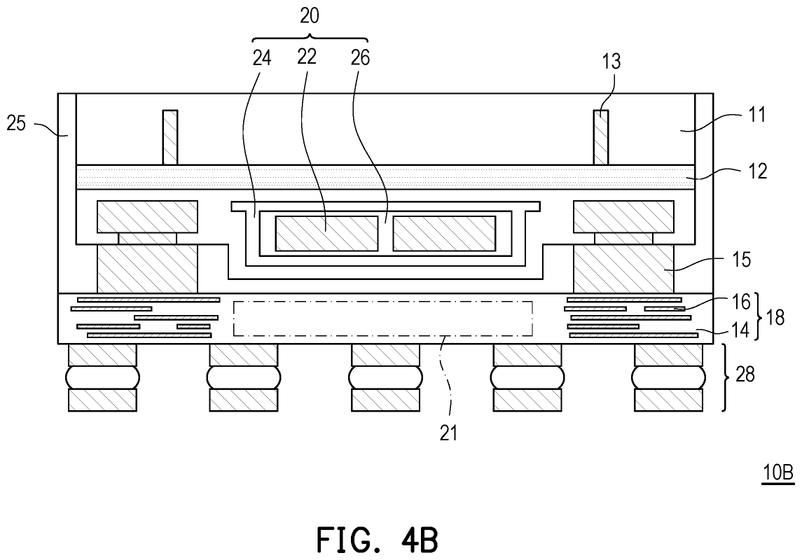

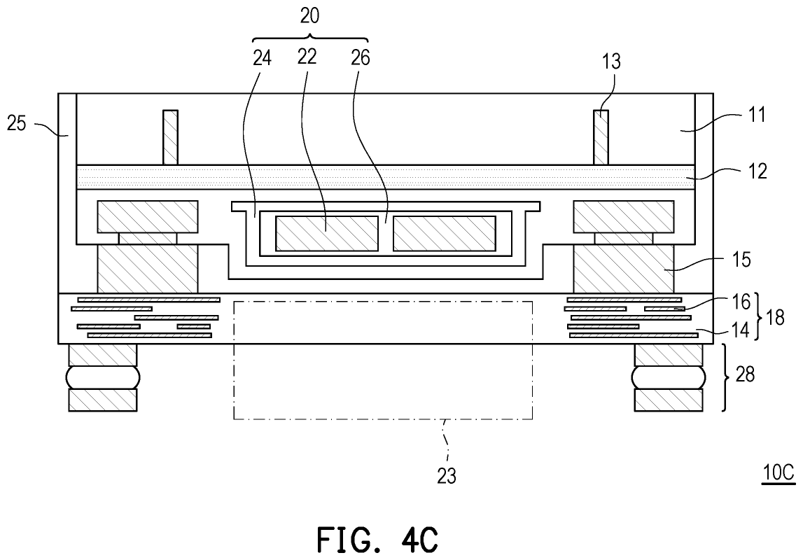

FIG. 4A illustrates an example first die 10A. In accordance with some embodiments of the present disclosure, the first die 10 include voltage regulators for regulating voltage supplies for the overlying dies. Specifically, the first die 10 may include a substrate 11, a device layer 12, an inductor device 20, an internal RDL structure 18, a plurality of conductive connectors 28, and an inductor contact 15.

In some embodiments, the substrate 11 may include silicon or other semiconductor materials. Alternatively, or additionally, the substrate 11 may include other elementary semiconductor materials such as germanium. In some embodiments, the substrate 11 is made of a compound semiconductor such as silicon carbide, gallium arsenic, indium arsenide or indium phosphide. In some embodiments, the substrate 11 is made of an alloy semiconductor such as silicon germanium, silicon germanium carbide, gallium arsenic phosphide, or gallium indium phosphide. In some embodiments, the substrate 11 includes an epitaxial layer. For example, the substrate 11 has an epitaxial layer overlying a bulk semiconductor.

The device layer 12 may be disposed on the substrate 11. In some embodiments, the device layer 12 is formed on the substrate 11 in a front-end-of-line (FEOL) process. The device layer 12 includes a wide variety of devices. In some embodiments, the devices comprise active components, passive components, or a combination thereof. In some embodiments, the devices may include integrated circuits devices. The devices are, for example, transistors, capacitors, resistors, diodes, photodiodes, fuse devices, or other similar devices. In some embodiments, the device layer 12 includes a gate structure, source/drain regions, and isolation structures, such as shallow trench isolation (STI) structures (not shown). In the device layer 12, various N-type metal-oxide semiconductor (NMOS) and/or P-type metal-oxide semiconductor (PMOS) devices, such as transistors or memories and the like, may be formed and interconnected to perform one or more functions. Other devices, such as capacitors, resistors, diodes, photodiodes, fuses and the like may also be formed on the substrate 11. The functions of the devices may include memory, processors, sensors, amplifiers, power distribution, input/output circuitry, or the like. In the present embodiment, the device layer 12 includes the power management integrated circuit (PMIC) for battery management, voltage regulation, charging functions, or the like. Alternately, the device layer 12 may include PMIC and system-on-a-chip (SoC) for logic function. In other embodiments, the device layer 12 may include SoC and high bandwidth memory for memory function.

The inductor device 20 may be disposed on and electrically connected to the device layer 12. In detail, the inductor device 20 may include a coil structure 22 and a magnetic material 24 wrapping the coil structure 22. The inductor device 20 further includes an insulator 26 separating the coil structure 22 from the magnetic material 24. In some embodiments, the coil structure 22 includes a metal material (e.g., copper), the magnetic material 24 includes Fe, Co, Ni or the like, and the insulator 26 includes a polymer material such as polyimide, PBO, or the like. In some alternative embodiments, the materials of the coil structure 22 and the magnetic material 24 may be exchanged. For example, the coil structure 22 may include Fe, Co, Ni or the like, and the magnetic material 24 may include copper. In addition, an interconnect structure (not shown) may be formed between the device layer 12 and the inductor device 20 to electrically couple the device layer 12 and the inductor device 20. Alternately, the inductor device 20 may be embedded in the interconnect structure to form a portion of the interconnect structure. The interconnect structure may include a plurality of dielectric layers, and metal lines and vias in the dielectric layers. The dielectric layers may include Inter Metal Dielectric (IMD) layers, which may be formed of low-k dielectric materials having dielectric constants (k values) lower than about 3.5, lower than about 3.0, or lower than about 2.5, for example. In other embodiments, the dielectric layers may include non-low-k passivation layers such as silicon nitride layers, silicon oxide layers, Un-doped Silicate Glass (USG) layers, and/or polymer layers.

The internal RDL structure 18 may be disposed on the inductor device 20. In detail, the internal RDL structure 18 may include one or more dielectric layers 14 and one or more conductive features 16 (sometimes referred to as redistribution layers or redistribution lines) embedded in the dielectric layers 14. More or fewer dielectric layers and conductive features may be formed in the internal RDL structure 18 according to the needs. In some embodiments, the dielectric layers 14 may be or may comprise an organic material such as a polymer, which may be a photo-sensitive polymer such as PBO, polyimide, or the like. The dielectric layers 14 may also be formed of or comprise an inorganic material such as silicon oxide, silicon nitride, or the like. In some embodiments, the conductive features 16 may be or may comprise a metal material such as copper or the like.

The conductive connectors 28 may be disposed on the internal RDL structure 18. In some embodiments, the conductive connectors 28 include solder regions, metal pillars, metal pads, metal bumps (sometimes referred to as micro-bumps), or the like. The material of the conductive connectors 28 may include non-solder materials, which may be formed of or comprise copper, nickel, aluminum, gold, multi-layers thereof, alloys thereof, or the like. The conductive connectors 28 may be electrically connected to the internal RDL structure 18.

The inductor contact 15 may be disposed aside the inductor device 20 and electrically connect the internal RDL structure 18 and the inductor device 20. In some embodiments, the inductor contact 15 include solder regions, metal pillars, metal pads, metal bumps (sometimes referred to as micro-bumps), or the like. The material of the inductor contact 15 may include non-solder materials, which may be formed of or comprise copper, nickel, aluminum, gold, multi-layers thereof, alloys thereof, or the like. Since the inductor device 20 may occupy a larger area, the number of the inductor contact 15 at the same level with the inductor device 20 cannot be increased. In this case, the smaller number of the inductor contact 15 may not be able to withstand the large current from the inductor device 20 and easily cause electromigration (EM) issue. Therefore, the internal RDL structure 18 may be disposed between the inductor contact 15 and the conductive connectors 28 to distribute the large current to the larger number of the conductive connectors 28, thereby preventing the EM issue. In some embodiments, the number of the conductive connectors 28 is greater than the number of the inductor contact 15.

As shown in FIG. 4A, the first die 10 further includes a planarization layer 25 encapsulating the substrate 11, the device layer 12, the inductor device 20, and the inductor contact 15 to contact an upper surface 18u of the internal RDL structure 18. In some embodiments, the planarization layer 25 may be or may comprise an organic material such as a polymer, which may be a photo-sensitive polymer such as PBO, polyimide, or the like. Alternately, the planarization layer 25 may also be formed of or comprise an inorganic material such as silicon oxide, silicon nitride, or the like. It should be noted that, in some embodiments, the inductor device 20 is separated from the upper surface 18u of the internal RDL structure 18 by a non-zero distance. That is, a portion of the planarization layer 25 may extend between the inductor device 20 and the upper surface 18u of the internal RDL structure 18, so that the inductor device 20 is not in contact with the upper surface 18u of the internal RDL structure 18. Further, the planarization layer 25 can provide the flat surface for formation of the internal RDL structure 18.

The first die 10 further includes a plurality of substrate-through vias (TSVs) 13 penetrating through the substrate 11 to electrically connect the device layer 12. The TSVs 13 are also sometimes referred to as through-silicon vias when formed in a silicon substrate. In some embodiments, the TSVs 13 include copper, nickel, solder, alloys thereof, or the like. Each of the TSVs 13 may be encircled by dielectric isolation liners, which are formed of a dielectric material such as silicon oxide, silicon nitride, or the like. The isolation liners electrically and physically isolate the respective TSVs 13 from the substrate 11. The TSVs 13 may extend from the device layer 12 to an intermediate level between the top surface and the bottom surface of the substrate 11. In some alternative embodiments, the TSVs 13 may penetrate through the device layer 12 to contact the interconnect structure between the device layer 12 and the inductor device 20. In some other embodiments, the TSVs 13 may penetrate through the device layer 12 to contact the inductor contact 15 aside the inductor contact 15.

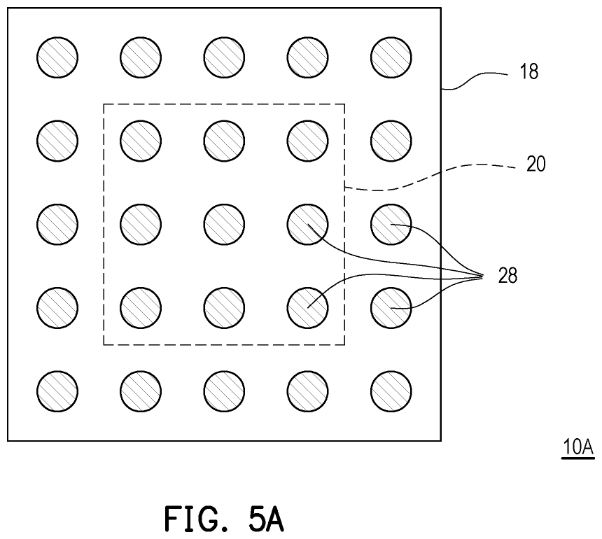

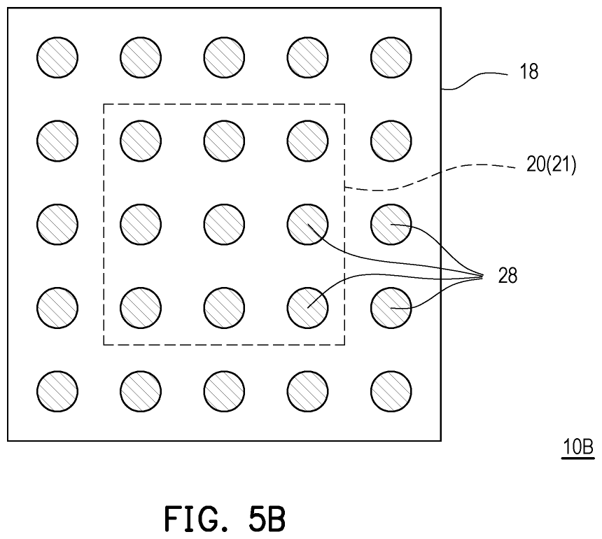

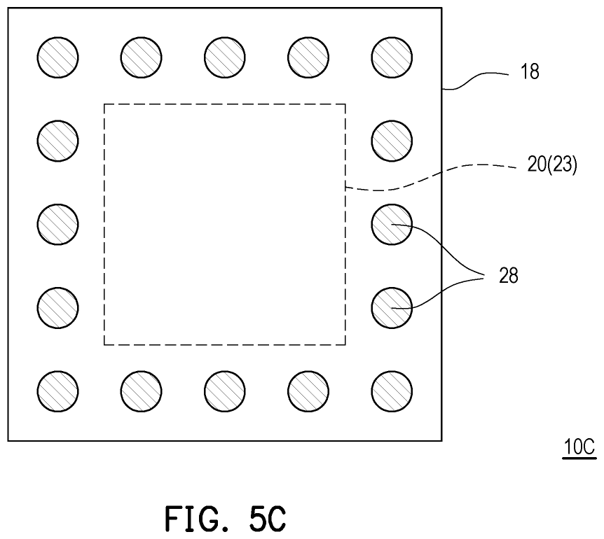

It should be noted that, in some embodiments, the conductive features 16 of the internal RDL structure 18 are across the inductor device 20, as shown in FIG. 4A. That is, the conductive features 16 of the internal RDL structure 18 may extend from one side of the inductor device 20 to opposite side of the inductor device 20, so that a portion of the conductive features 16 is located directly under (or directly over, if the first die 10A is flipped) the inductor device 20. In addition, the conductive connectors 28 may be disposed directly under (or directly over, if the first die 10A is flipped) the inductor device 20 in an array arrangement from a plan view of the internal RDL structure 28, as shown in FIG. 5A.

However, the embodiments of the present disclosure are not limited thereto. In some alternative embodiments, the conductive features 16 of the internal RDL structure 18 laterally surround the inductor device 20 in a circular arrangement, so that the conductive features 16 of the internal RDL structure 18 are not disposed directly under (or not directly over, if the first die 10A is flipped) the inductor device 20, as shown in FIG. 4B. In the example first die 10B, the conductive connectors 28 may be disposed directly under (or directly over, if the first die 10A is flipped) the inductor device 20 in an array arrangement from a plan view of the internal RDL structure 28, as shown in FIG. 5B. In such embodiment, a region 21 of the internal RDL structure 18 vertically between the conductive connectors 28 and the inductor device 20 is only filled with the dielectric material and does not have any conductive features, so as to reduce the unnecessary electrical coupling. The conductive connectors 28 may also support the region 21 of the internal RDL structure 18 to maintain the mechanical strength.

In some other embodiments, the conductive features 16 of the internal RDL structure 18 laterally surround the inductor device 20 in a circular arrangement, so that the conductive features 16 of the internal RDL structure 18 are not disposed directly under (or not directly over, if the first die 10A is flipped) the inductor device 20, as shown in FIG. 4C. In the example first die 10C, the conductive connectors 28 also laterally surround the inductor device 20 in the circular arrangement from a plan view of the internal RDL structure 18, as shown in FIG. 5C. In such embodiment, a region 23 of the internal RDL structure 18 is only filled with the dielectric material and does not have any conductive features and no conductive connector is included in the region 23 (i.e., directly under the inductor device 20), so as to further avoid the unnecessary electrical coupling.

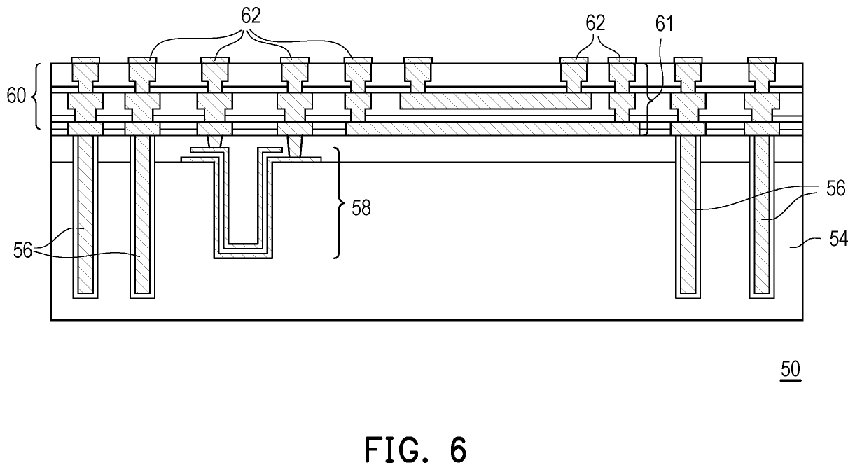

FIG. 6 illustrates an example second die 50 in accordance with some embodiments. It is appreciated that the second die 50 represents some of the possible structures of the second die, and may include one or more of features such as through-vias, interconnect paths, capacitors, and the like. The second die 50 may include a substrate 54, which may be a semiconductor substrate such as a silicon substrate. The substrate 54 may also be a dielectric substrate, which is formed of a dielectric material such as silicon oxide, silicon nitride, or the like. In accordance with some embodiments, there is no through-via formed to extend into, regardless of whether the substrate 54 is formed of a semiconductor or a dielectric material. In accordance with alternative embodiments, through-vias 56 are formed to extend into the substrate 54.

In some embodiments, the second die 50 is free from active devices such as transistors and diodes therein. The second die 50 may or may not include passive devices such as capacitors, transformers, inductors, resistors, and the like. In some alternative embodiments, the second die 50 include passive devices. For example, the second die 50 may be an IPD die including a capacitor 58 (which may be a deep-trench capacitor) formed in the second die 50. The second die 50 may also be an IPD die including a resistor therein.

The second die 50 may act as a bridge die (sometimes referred to as a local silicon interconnect (LSI)), and may include an interconnect structure 60 over the substrate 54. The interconnect structure 60 further includes dielectric layers and metal lines and vias in the dielectric layers. The dielectric layers may include Inter-Metal Dielectric (IMD) layers. In accordance with some embodiments, some of the dielectric layers are formed of low-k dielectric materials having dielectric constant values (k-value) lower than 3.8, and the k-values may be lower than about 3.0 or about 2.5. The low-k dielectric layers may be formed of a carbon-containing low-k dielectric material, Hydrogen SilsesQuioxane (HSQ), MethylSilsesQuioxane (MSQ), or the like. The formation of the metal lines and vias may include single damascene and dual damascene processes. A bond structures 62 such as metal pillars or metal pads are formed at the surface of the second die 50. The second die 50 may include bridges 61, which include metal lines and vias. Each of the bridges 61 is connected to two bond structures, so that the bridges 61 may be used to electrically interconnect two or more package components (such as device dies) in subsequent processes.

Referring back to FIG. 3, in accordance with some embodiments, the bonding of the first die 10 and the second die 50 to the RDLs 46 may be performed through solder bonding or metal-to-metal direct bonding. For example, the first die 10 may be bonded to the RDLs 46 of the first RDL structure 48 through the conductive connectors 28, while the second die 50 may be bonded to the RDLs 46 of the first RDL structure 48 through the solder regions 64. After the bonding, an underfill 66 is dispensed into the gaps between the first die 10, the second die 50, and their corresponding underlying first RDL structure 48, and is then cured. In accordance with some embodiments, the underfill 66 may include a base material, which may include a polymer, a resin, an epoxy, and/or the like, and filler particles in the base material. The filler particles may be dielectric particles of silica, alumina, boron nitride, or the like, and may have spherical shapes.

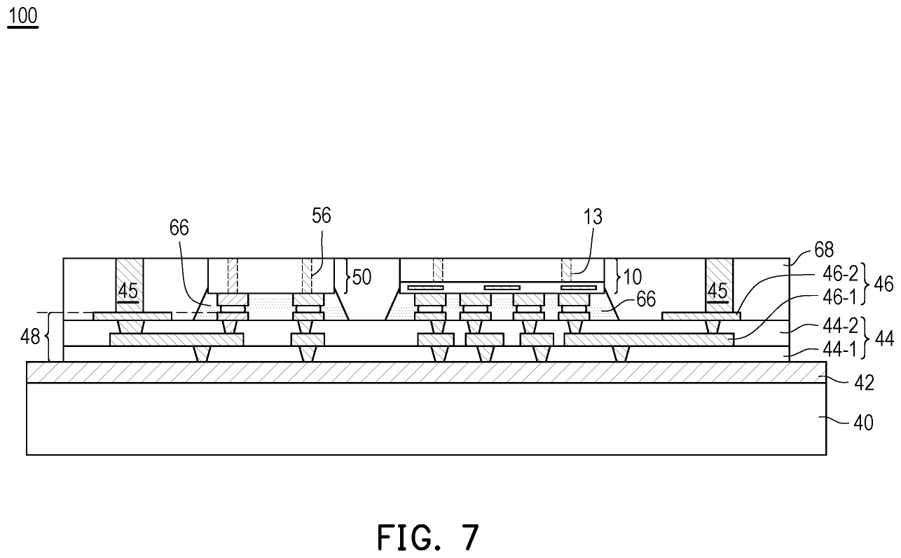

Referring to FIG. 7, an encapsulant 68 is dispensed to encapsulate the first die 10, the second die 50, and the conductive vias 45. The encapsulant 68 fills the gaps between the first die 10, the second die 50, and the conductive vias 45. The encapsulant 68 may include a molding compound, a molding underfill, an epoxy, and/or a resin. When the encapsulation is finished, a top surface of the encapsulant 68 is higher than the top surfaces of the conductive vias 45 and top surfaces of the second die 50 and the first die 10. The encapsulant 68 may include a base material, which may be a polymer, a resin, an epoxy, or the like, and filler particles in the base material. The filler particles may be dielectric particles of silica, alumina, boron nitride, or the like, and may have spherical shapes.

A planarization process such as a Chemical Mechanical Polish (CMP) process or a mechanical grinding process is then performed to thin encapsulant 68, the first die 10, and the second die 50, until the top surfaces of the conductive vias 45 are revealed. In addition, a portion of the substrate 11 of the first die 10 is removed to expose the top surfaces of the TSVs 13, and a portion of the substrate 54 of the second die 50 is also removed to expose the top surfaces of the through-vias 56. In this case, the top surfaces of the TSVs 13 and the through-vias 56 are substantially level with the top surface of the encapsulant 68 after planarization process. The conductive vias 45 may be alternatively referred to as insulator-through vias (TIVs) since they penetrate through the encapsulant 68.

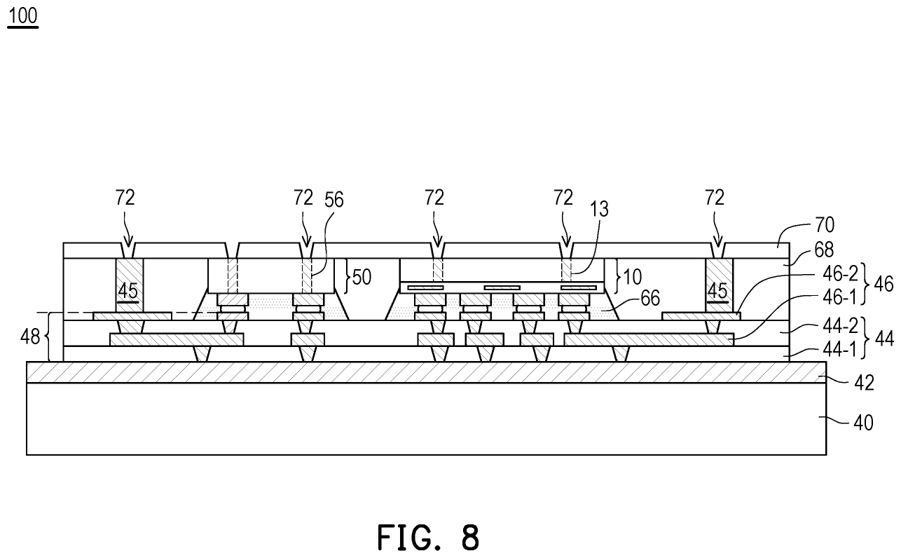

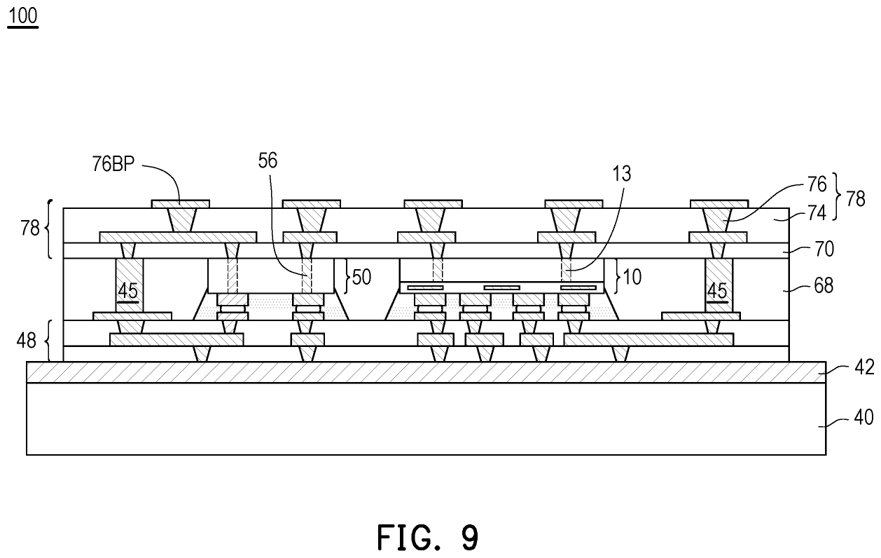

FIG. 8 illustrates the formation and the patterning of a dielectric layer 70 in accordance with some embodiments. The dielectric layer 70 may be part of the subsequently formed a second RDL structure 78 (shown in FIG. 9). The dielectric layer 70 may be or may comprise an organic material such as a polymer, which may be a photo-sensitive polymer such as PBO, polyimide, or the like. The dielectric layer 70 may also be formed of or comprise an inorganic material such as silicon oxide, silicon nitride, or the like. The dielectric layer 70 may be formed using a process such as lamination, coating, (e.g., spin-coating), chemical vapor deposition (CVD), or the like.

The dielectric layer 70 is patterned using acceptable photolithography and etching techniques to form openings 72, with the TIVs 45, the TSVs 13 of the first die 10, and the through-vias 56 of the second die 50 being exposed through the openings 72.

FIG. 8 and FIG. 9 illustrate the formation of the second RDL structure 78 over the first die 10 and the second die 50. In accordance with some embodiments, the second RDL structure 78 includes one or more dielectric layers 74. In some embodiments, the dielectric layers 74 are formed of a non-photo-sensitive material such as molding compound, molding underfill, silicon oxide, silicon nitride, or the like. The dielectric layers 74, on the other hand, may be formed of a photo-sensitive material(s) such as PBO, polyimide, or the like. In some embodiments, the dielectric layers 74 may be formed using a process such as lamination, coating, (e.g., spin-coating), chemical vapor deposition (CVD), atomic layer deposition (ALD), or the like.

RDLs 76 may be formed in the dielectric layers 74. In some embodiments, the RDLs 76 include copper, or the like, and are electrically connected to the TIVs 45, the TSVs 13 of the first die 10, and the through-vias 56 of the second die 50. In an embodiment, the RDLs 76 may be formed by depositing a seed layer, after which a photoresist is placed and patterned on top of the seed layer in a desired pattern for the RDLs 76, and conductive material (e.g., copper, or the like) may then be formed in the patterned openings of the photoresist using e.g., a plating process. The photoresist may then be removed and the seed layer etched, forming the RDL 76. In some alternative embodiments, Each RDL 76 may be formed by a damascene process. As an example of a damascene process, the dielectric layer 74 is formed, and then the dielectric layer 74 is etched to form openings according to a defined photoresist pattern. Then, a seed layer of copper is deposited conformally over the surface and in the openings of the dielectric layer 74, after which an electroplating step or a deposition process is used to form conductive material (e.g., copper, or the like) in the openings of the RDLs 76. A planarization process is then performed to remove any excess conductive material and seed layer. Some surface conductive features 76BP are formed, which may be parts of the RDLs 76, or may be separately formed Under-Bump Metallurgies (UBMs). In some embodiments, the second RDL structure 78 are electrically connected to the first RDL structure 48 through the TIVs 45, the TSVs 13 of the first die 10, and the through-vias 56 of the second die 50.

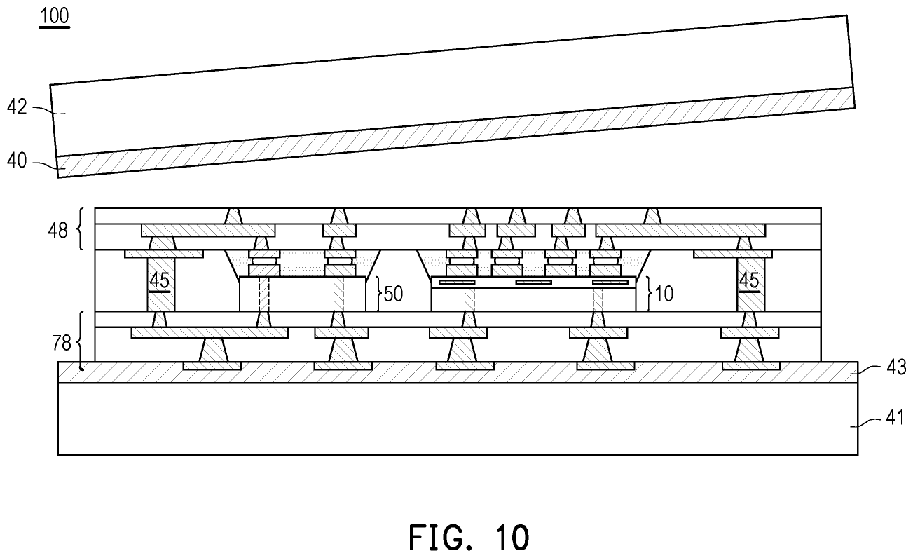

In a subsequent process, as shown in FIG. 10, a carrier-switch process is performed. In the carrier-switch process, the second RDL structure 78 is first attached to a carrier 41 through a release film 43. The carrier 41 is formed of a transparent material, and may be a glass carrier, a ceramic carrier, or the like. The release film 43 may be formed of an LTHC coating material. The carrier 40 is then de-bonded from the first RDL structure 48. In the de-bonding process, a light beam (which may be a laser beam) is projected on the release film 42, and the light beam penetrates through the transparent carrier 40. The release film 42 is thus decomposed. The carrier 40 may be lifted off from the release film 42, and hence the package structure 100 is de-bonded (demounted) from the carrier 40.

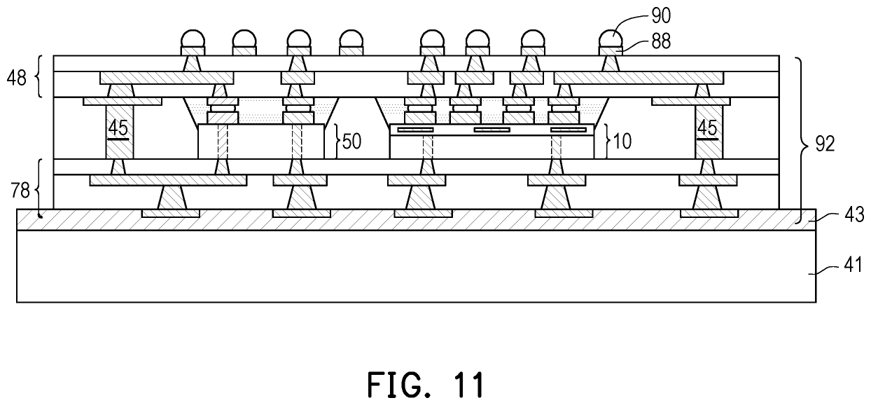

FIG. 11 illustrates the formation of UBMs 88 and conductive connectors 90 in accordance with some embodiments. The UBMs 88 may be formed of or comprise nickel, copper, titanium, or multi-layers thereof. The conductive connectors 90 are then formed on the UBMs 88. The formation of the conductive connectors 90 may include placing solder balls on the exposed portions of the UBMs 88, and then reflowing the solder balls, and hence the conductive connectors 90 are solder regions. In accordance with alternative embodiments of the present disclosure, the formation of the conductive connectors 90 includes performing a plating process to form solder layers, and then reflowing the solder layers. The conductive connectors 90 may also include non-solder metal pillars, or may have composite structures including metal pillars and solder caps over the non-solder metal pillars, which may also be formed through plating. Throughout the description, the structure over the release film 43 is referred to as an interposer 92. In some alternative embodiments, the second die 50 may be omitted, and only one or more first dies 10 are embedded in the interposer 92.

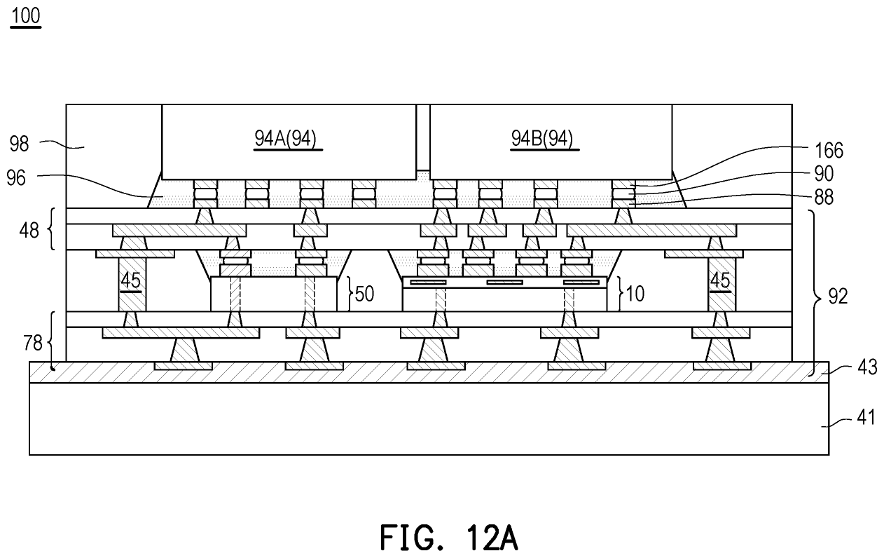

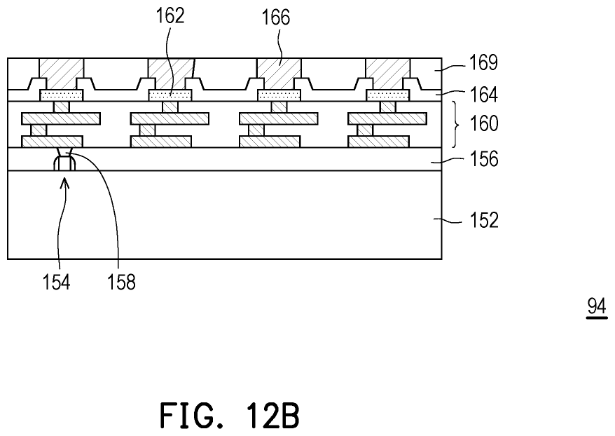

Referring to FIG. 12A, a plurality of package components 94 are bonded to the interposer 92. FIG. 12B illustrates a detailed view of an example package component 94 when the package component 94 is an integrated circuit die. The package component 94 may be formed in a wafer, which may include different device regions that are singulated in subsequent steps to form a plurality of integrated circuit dies. The package component 94 may be processed according to applicable manufacturing processes to form integrated circuits. For example, the package component 94 includes a semiconductor substrate 152, such as silicon, doped or undoped, or an active layer of a semiconductor-on-insulator (SOI) substrate. The semiconductor substrate 152 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 152 has an active surface (e.g., the surface facing upwards in FIG. 12B), sometimes called a front side, and an inactive surface (e.g., the surface facing downwards in FIG. 12B), sometimes called a back side.

Devices (represented by a transistor) 154 may be formed at the front surface of the semiconductor substrate 152. The devices 154 may be active devices (e.g., transistors, diodes, etc.), capacitors, resistors, etc. An inter-layer dielectric (ILD) 156 is over the front surface of the semiconductor substrate 152. The ILD 156 surrounds and may cover the devices 154. The ILD 156 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

Conductive plugs 158 may extend through the ILD 156 to electrically and physically couple the devices 154. For example, when the devices 154 are transistors, the conductive plugs 158 may couple the gates and source/drain regions of the transistors. Source/drain region(s) may refer to a source or or a drain, individually or collectively dependent upon the context. The conductive plugs 158 may be formed of tungsten, cobalt, nickel, copper, silver, gold, aluminum, the like, or combinations thereof.

An interconnect structure 160 is over the ILD 156 and conductive plugs 158. The interconnect structure 160 interconnects the devices 154 to form an integrated circuit. The interconnect structure 160 may be formed by, for example, metallization patterns in dielectric layers on the ILD 156. The metallization patterns include metal lines and vias formed in one or more low-k dielectric layers. The metallization patterns of the interconnect structure 160 are electrically coupled to the devices 154 by the conductive plugs 158.

The package component 94 further includes pads 162, such as aluminum pads, to which external connections are made. The pads 162 are on the active side of the package component 94, such as in and/or on the interconnect structure 160. One or more passivation films 164 are on the package component 94, such as on portions of the interconnect structure 160 and pads 162. Openings extend through the passivation films 164 to the pads 162. Die connectors 166, such as conductive pillars (for example, formed of a metal such as copper), extend through the openings in the passivation films 164 and are physically and electrically coupled to respective ones of the pads 162. The die connectors 166 may be formed by, for example, plating, or the like. The die connectors 166 electrically couple the respective integrated circuits of the package component 94.

Optionally, solder regions (e.g., solder balls or solder bumps) may be disposed on the pads 162. The solder balls may be used to perform chip probe (CP) testing on the package component 94. CP testing may be performed on the package component 94 to ascertain whether the package component 94 is a known good die (KGD). Thus, only package components 94, which are KGDs, undergo subsequent processing and are packaged, and dies, which fail the CP testing, are not packaged. After testing, the solder regions may be removed in subsequent processing steps.

A dielectric layer 169 may (or may not) be on the active side of the package component 94, such as on the passivation films 164 and the die connectors 166. The dielectric layer 169 laterally encapsulates the die connectors 166, and the dielectric layer 169 is laterally coterminous with the package component 94. Initially, the dielectric layer 169 may bury the die connectors 166, such that the topmost surface of the dielectric layer 169 is above the topmost surfaces of the die connectors 166. In some embodiments where solder regions are disposed on the die connectors 166, the dielectric layer 169 may bury the solder regions as well. Alternatively, the solder regions may be removed prior to forming the dielectric layer 169.

The dielectric layer 169 may be a polymer such as PBO, polyimide, BCB, or the like; a nitride such as silicon nitride or the like; an oxide such as silicon oxide, PSG, BSG, BPSG, or the like; the like, or a combination thereof. The dielectric layer 169 may be formed, for example, by spin coating, lamination, chemical vapor deposition (CVD), or the like. In some embodiments, the die connectors 166 are exposed through the dielectric layer 169 during formation of the package component 94. In some embodiments, the die connectors 166 remain buried and are exposed during a subsequent process for packaging the package component 94. Exposing the die connectors 166 may remove any solder regions that may be present on the die connectors 166.

In some embodiments, the package components 94 may include package components 94A, 94B having different functions. The package component 94A may include compute or logic dies, such as Central Processing Units (CPUs), Application processors (APs), system on chips (SOCs), Application Specific Integrated Circuits (ASICs), or the like. The package component 94B may include memory dies, such as Dynamic Random Access Memory (DRAM) dies, Static Random Access Memory (SRAM) dies, High-Bandwidth Memory (HBM) dies, Micro-Electro-Mechanical System (MEMS) dies, Hybrid Memory Cube (HMC) dies, or the like. However, the embodiments of the present disclosure are not limited thereto. In some alternative embodiments, the package components 94A, 94B may have the same function. For example, the package components 94A, 94B both include HBM dies. Although two kinds of package components 94 are illustrated, fewer or more kinds of package components 94 may be used.

After bonding the package components 94 to the interposer 92, an underfill 96 is dispensed into the gap between package components 94 and the underlying interposer 92. The package components 94 are then encapsulated in the encapsulant 98, which may include a molding compound, a molding underfill, or the like. The encapsulant 98 may include a base material, which may be a polymer, a resin, an epoxy, or the like, and filler particles in the base material. The filler particles may be dielectric particles of silica, alumina, boron nitride, or the like, and may have spherical shapes.

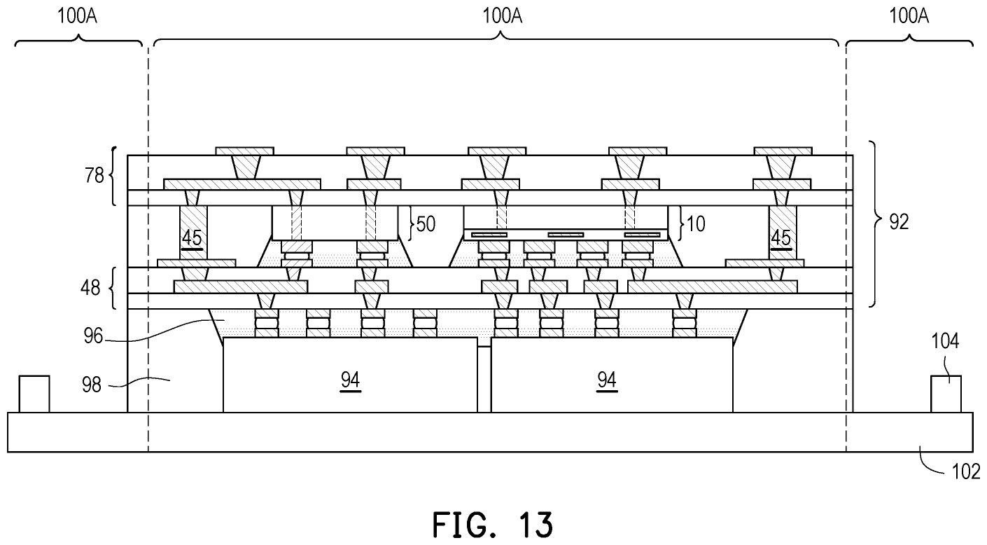

Referring to FIG. 13, the package structure 100 is de-bonded (demounted) from the carrier 41. The de-bonding may be performed, for example, by projecting a light beam (which may be a laser beam) on the release film 43, and the light beam penetrates through the transparent carrier 41. Release film 43 is thus decomposed. The carrier 41 is lifted off from the release film 43, and hence the package structure 100 is de-bonded (demounted) from the carrier 41. The resulting package structure 100 is shown in FIG. 13. The package structure 100 is then placed on a tape 102, which may be fixed on a frame 104. In accordance with some embodiments, the package structure 100 is singulated in a sawing process, and is separated into a plurality of packages 100A that have structures identical to each other.

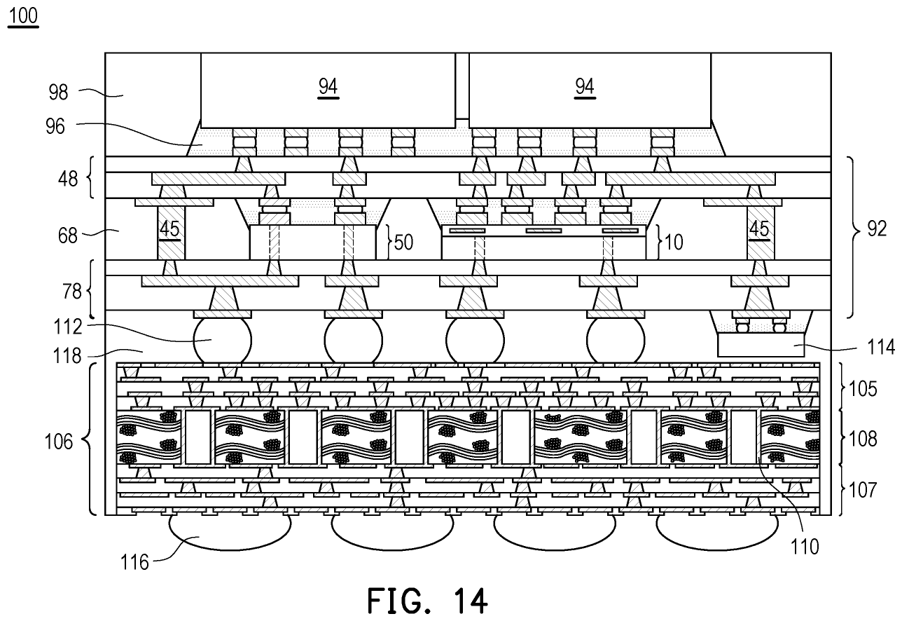

FIG. 14 illustrates the bonding of an IPD die 114 and a package substrate 106 to the package structure 100. The IPD die 114 may be a capacitor die, an inductor die, a resistor die, or the like. The package substrate 106 may include organic dielectric layers, and are sometimes referred to as organic package substrates. The package substrate 106 may also be cored package substrates including cores, or may be core-less package substrates that do not have cores therein. For example, the package substrate 106 may include a dielectric core 108, and plating through-holes (PTHs, which are conductive pipes) 110 therein. In addition, the package substrate 106 may include one or more PTHs 111 extending through the dielectric core 108, wherein the PTHs 111 may be similar in structure and dimensions as the PTH 110. The package substrate 106 may comprise routing structures 105 and 107 formed using dielectric layers and conductive routing layers within the dielectric layers. The routing structures 105 and 107 are formed on opposite sides of the dielectric core 108 and may provide additional electrical routing within the package substrate 106.

In accordance with alternative embodiments, the package substrate 106 is in an un-sawed wafer, and is bonded to the package structure 100 through wafer-to-wafer bonding or die-to-wafer bonding (with the packages 100A being in the die form). In accordance with alternative embodiments, the package substrate 106 is a discrete substrate, and is bonded to the package structure 100 through die-to-die bonding. The package substrate 106 is free from active devices such as transistors and diodes therein. The bonding may be achieved through conductive terminals 112. The conductive terminals 112 are formed by initially forming a layer of solder through evaporation, electroplating, printing, solder transfer, ball placement, or the like. Once a layer of solder has been formed on the structure, a reflow may be performed in order to shape the material into the desired bump shapes. The package substrate 106 may also comprise conductive connectors 116 that may be ball grid array (BGA) connectors, solder balls, or the like. The conductive connectors 116 may be used to input electrical signals to the package structure 100. The conductive connectors 116 may include a conductive material such as solder, copper, aluminum, gold, nickel, silver, palladium, tin, the like, or a combination thereof.

An underfill 118 is dispensed into the gaps between the package substrate 106 and the interposer 92, such as around the conductive terminals 112 and the IPD die 114. In addition, the underfill 118 is dispensed so as to be disposed on sidewalls of the package substrate 106. In accordance with some embodiments, the underfill 118 may include a base material, which may include a polymer, a resin, an epoxy, and/or the like, and filler particles in the base material. The filler particles may be dielectric particles of silica, alumina, boron nitride, or the like, and may have spherical shapes. The underfill 118 may physically isolate the IPD die 114 from the package substrate 106.

In accordance with some embodiments, the first die 10 and the second die 50 are embedded in the interposer 92. The first die 10 and the second die 50 are electrically and signally connected to the package components 94. The first die 10 may include the device layer 12 and the inductor device 20 electrically connected to each other. As shown in FIG. 4A and FIG. 14, an electrical signal input through the conductive connectors 116, the package substrate 106, and the conductive terminals 112 is transmitted to the device layer 12 having PMIC through the second RDL structure 78 and the TSVs 13, where this electrical signal undergoes a first voltage regulation. After the first voltage regulation, the electrical signal is further transmitted to the inductor device 20 through the interconnect structure, where it undergoes a second voltage regulation. This double regulation results in better voltage regulation of the signal before this electrical signal is transmitted to the overlying plurality of package components 94.

In addition, the internal RDL structure 18 is configured to redistribute the electrical signal (e.g., current) from the inductor contact 15 to the conductive connectors 28. In some embodiments, the number of the conductive connectors 28 is greater than the number of the inductor contact 15. As such, the internal RDL structure 18 can redistribute large current from fewer inductor contact 15 to more conductive connectors 28, thereby preventing the electromigration (EM) failure. In this case, more conductive connectors 28 may be arranged in an array, circular, or ring configuration to efficiently support voltage output to the overlying package components 94 (e.g., SoC and/or HBM). Compared with the conventional IVR die mounted on the package substrate, the first die 10 with the PMIC device layer 12 and the inductor device 20 is embedded in the interposer 92 which is closer the overlying package components 94 than the conventional IVR die. In such embodiment, the shortened distance can prevent the unnecessary power loss and parasitic capacitance, so that the electrical signal has better voltage regulation before this electrical signal is transmitted to the overlying package components 94. Further, the first die 10 with the device layer 12 is embedded in the interposer 92, so that the active components (e.g., logic and/or memory components) in the device layer 12 can communicate the overlying package components 94 (e.g., SoC and/or HBM) through the vertical conductive path rather than through the lateral RDL structure. As a result, the transmission speed between the first die 10 and the overlying package components 94 will become faster, thereby improving the performance of the package structure 100.

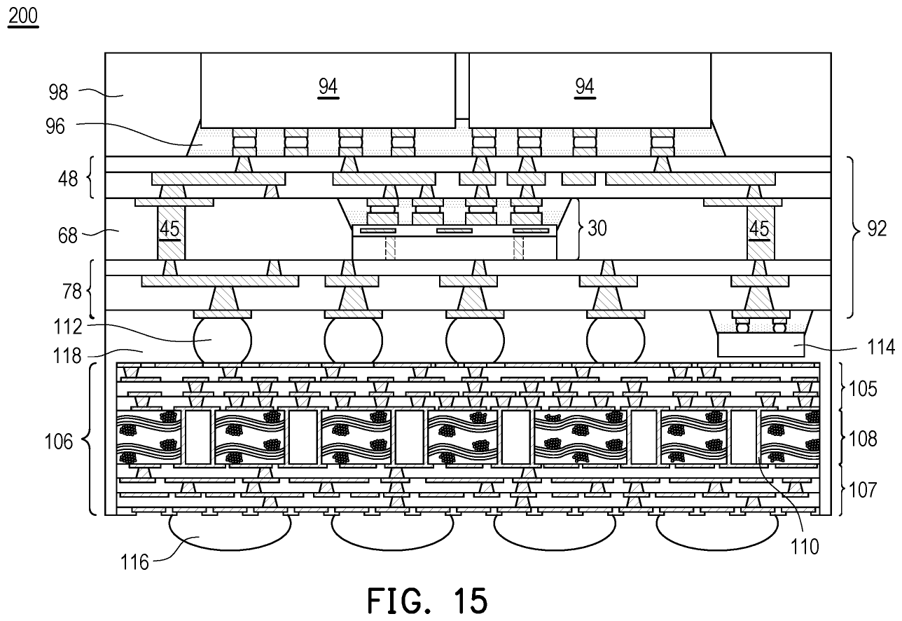

FIG. 15 illustrates a package structure 200 in accordance with an alternative embodiment. Unless specified otherwise, like reference numerals in this embodiment (and subsequently discussed embodiments) represent like components in the embodiment shown in FIG. 1 through FIG. 14 formed by like processes. Accordingly, the process steps and applicable materials may not be repeated herein.

The package structure 200 illustrated in FIG. 15 differs from the package structure 100 illustrated in FIG. 14 in that the first die 10 and the second die 50 are replaced by a die stack structure 30, and the die stack structure 30 is encapsulated by the encapsulant 68 and integrated in the interposer 92.

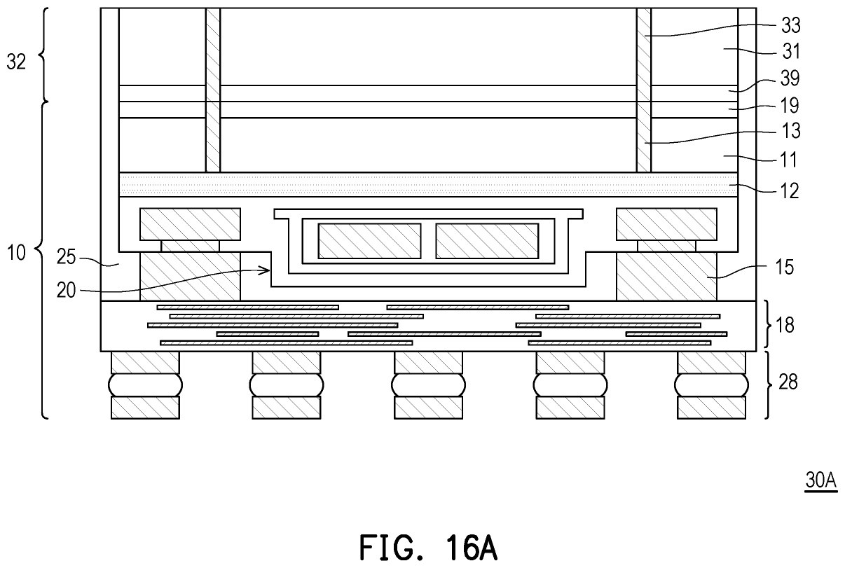

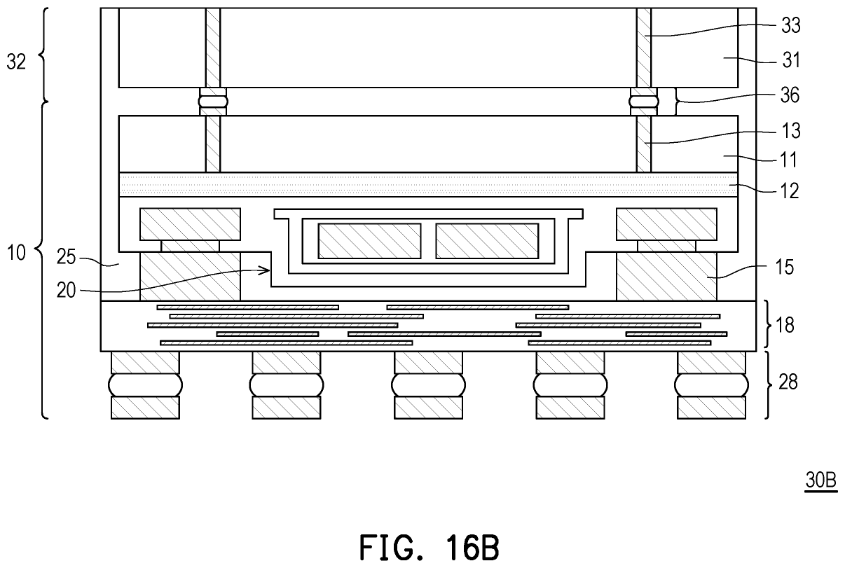

FIG. 16A illustrates an example die stack structure 30A in accordance with some embodiments. The die stack structure 30A may include a second die 32 stacked on the first die 10. The first die 10 is similar the example first die 10A, 10B, or 10C, and the configuration, the material, the forming method may not be repeated herein. In some embodiments, the second die 32 may be stacked on the first die 10 in a face-to-back configuration. That is, the active surface (or frontside) of the second die 32 may face toward the non-active surface (or backside) of the first die 10. However, the embodiments of the present disclosure are not limited thereto. In some other embodiments, the second die 32 may be stacked on the first die 10 in the face-to-face or back-to-back configuration.

In some embodiments, the second die 32 may include a substrate 31 and a plurality of TSVs 33 penetrating through the substrate 31. The second die 32 may be bonded onto the first die 10 through hybrid bonding or direct bonding. In general, the hybrid bonding includes both a dielectric-to-dielectric bonding and a metal-to-metal (copper-to copper) bonding. In some embodiments, the dielectric-to-dielectric bonding is a fusion bonding or an oxide-to-oxide bonding. Specifically, a bonding dielectric layer 19 may be formed on the substrate 11, and another bonding dielectric layer 39 may be formed on the substrate 31. The second die 32 may be picked-and-placed onto the first die 10, so that the first die 10 is in contact with the second die 32. In addition, the TSVs 33 of the second die 32 are substantially aligned and in direct contact with the corresponding TSVs 13 of the first die 10, and the bonding dielectric layer 39 is directly in contact with at least a portion of the bonding dielectric layer 19. In some embodiments, to facilitate the hybrid bonding between the first die 10 and the second die 32, surface preparation for the surfaces to be bonded may be performed. The surface preparation may include surface cleaning and activation, for example.

After cleaning the bonding surfaces, activation of the bonding surfaces of the bonding dielectric layers 19 and 39 may be performed for development of high bonding strength. For example, plasma activation may be performed to treat the top surfaces of the bonding dielectric layers 19 and 39. After the activated the top surfaces of the bonding dielectric layers 19 and 39 are in contact with each other, a hybrid bonding step is performed. The hybrid bonding step may include a thermal treatment process for dielectric bonding and a thermal annealing process for conductor bonding. In some embodiments, the temperature of the thermal annealing process for conductor bonding is higher than the temperature of the thermal treatment process for dielectric bonding. After performing the thermal annealing process for conductor bonding, the bonding dielectric layer 19 is bonded to the overlying bonding dielectric layer 39, and the TSVs 33 are bonded to the underlying TSVs 13.

In some embodiments, one or more dies may be stacked on the first die 10 to form the die stack structure 30 with multiple functions. In this case, the horizontal footprint in the interposer 92 can be effectively reduced to accommodate more dies, die stack structures, and or other components. In addition, the die stack structure 30 with multiple functions can reduce the unnecessary communication with the overlying package components 94 to further increase the operation speed, thereby improving the performance of the package structure 200. Further, the first die 10 and the stacked second die 32 are KGDs, undergo subsequent processing and are packaged, and dies, which fail the CP testing, are not packaged. As such, the yield and the production capacity of the package structure 200 can be improved.

FIG. 16B illustrates an example die stack structure 30B in accordance with some embodiments. The die stack structure 30B differs from the die stack structure 30A in that the second die 32 may be bonded onto the first die 10 through solder bonding. Specifically, the second die 32 may be bonded onto the first die 10 through solder regions 36. In some embodiments, the formation of the solder regions 36 may include placing solder balls on the exposed portions of the TSVs 13, and then reflowing the solder balls. In accordance with alternative embodiments of the present disclosure, the formation of the solder regions 36 includes performing a plating process to form solder layers, and then reflowing the solder layers. The solder regions 36 may also include non-solder metal pillars, or may have composite structures including metal pillars and solder caps over the non-solder metal pillars, which may also be formed through plating.

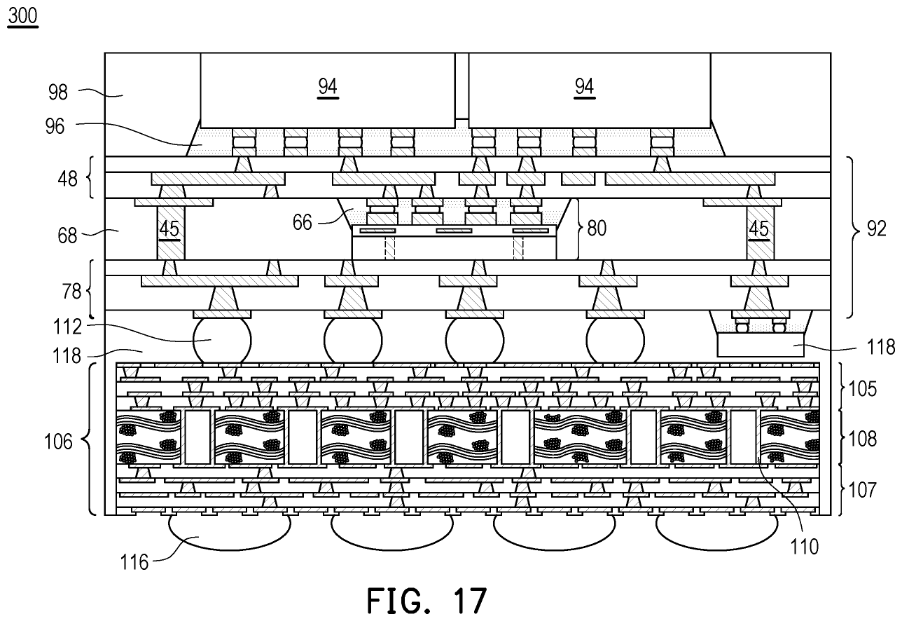

FIG. 17 illustrates a package structure 300 in accordance with an alternative embodiment. Unless specified otherwise, like reference numerals in this embodiment (and subsequently discussed embodiments) represent like components in the embodiments shown in FIG. 1 through FIG. 14 formed by like processes. Accordingly, the process steps and applicable materials may not be repeated herein.

The package structure 300 illustrated in FIG. 17 differs from the package structure 100 illustrated in FIG. 14 in that the first die 10 and the second die 50 are replaced by a package component 80, and the package component 80 is encapsulated by the encapsulant 68 and integrated in the interposer 92.

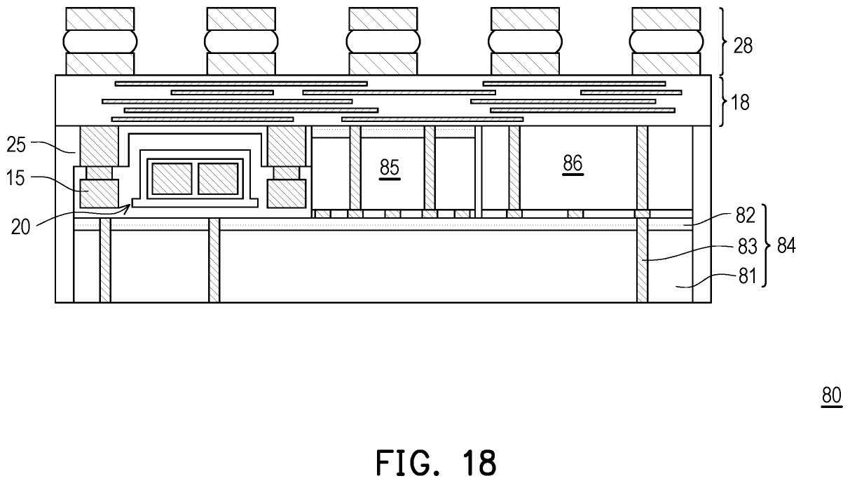

FIG. 18 illustrates an example package component 80 in accordance with some embodiments. The package component 80 may include a bottom die 84, an inductor device 20, an active device die 85, a passive device die 86, an internal RDL structure 18, and a plurality of conductive connectors 28.

In some embodiments, the bottom die 84 may include a substrate 81, a device layer 82 on the substrate 81, and a plurality of TSVs 83 penetrating through the substrate 81 to contact the device layer 82. The inductor device 20, the active device die 85, and the passive device die 86 may be arranged side by side on the bottom die 84. In some embodiments, the active device die 85 may be or include a compute die, a logic die, a memory die, or the like. The passive device die 86 may be or include an IPD die including a capacitor therein, an IPD die including a resistor therein, an interconnect die for bridging two device dies, and/or the like. The active device die 85 and the passive device die 86 may have different functions, and may be bonded onto the bottom die 84 through solder bonding or metal-to-metal direct bonding. The active device die 85 and the passive device die 86 may be bonded onto the bottom die 84 in the face-to-face configuration, the face-to-back configuration, or the back-to-back configuration.

The internal RDL structure 18 may be disposed on the inductor device 20, the active device die 85, and the passive device die 86. The conductive connectors 28 may be disposed on the internal RDL structure 18. The package component 80 further includes a planarization layer 25 encapsulating the bottom die 84, the inductor device 20, the active device die 85, and the passive device die 86. An underfill 66 is dispensed into the gap between the package component 80 and the underlying first RDL structure 48, and is then cured.

It should be noted that the internal RDL structure 18 is configured to redistribute the electrical signal (e.g., current) from the inductor contact 15 to the conductive connectors 28. In some embodiments, the number of the conductive connectors 28 is greater than the number of the inductor contact 15. As such, the internal RDL structure 18 can redistribute large current from fewer inductor contact 15 to more conductive connectors 28, thereby preventing the electromigration (EM) failure. In addition, one or more dies may be laterally stacked on the bottom die 84 to form the package component 80 with multiple functions. In this case, the horizontal footprint in the interposer 92 can be effectively reduced to accommodate more dies, package components, and or other components. In addition, the package component 80 with multiple functions can reduce the unnecessary communication with the overlying package components 94 to further increase the operation speed, thereby improving the performance of the package structure 300. Further, the bottom die 84, the active device die 85, and the passive device die 86 are KGDs, undergo subsequent processing and are packaged, and dies, which fail the CP testing, are not packaged. As such, the yield and the production capacity of the package structure 300 can be improved.

According to some embodiments, a package structure includes an interposer at least including a first die sandwiched between a first redistribution layer (RDL) structure and a second RDL structure. The first die includes: a device layer disposed on a substrate; an inductor device disposed on the device layer; an internal RDL structure disposed on the inductor device; a plurality of conductive connectors disposed on the internal RDL structure; and an inductor contact disposed aside the inductor device and electrically connecting the internal RDL structure and inductor device. The number of the plurality of conductive connectors is greater than the number of the inductor contact.

In some embodiments, the internal RDL structure has a conductive feature across the inductor device. In some embodiments, a conductive feature of the internal RDL structure laterally surrounds the inductor device in a circular arrangement, so that the conductive feature of the internal RDL structure is not disposed directly over the inductor device. In some embodiments, the plurality of conductive connectors laterally surround the inductor device in a circular arrangement from a plan view of the internal RDL structure. In some embodiments, the plurality of conductive connectors are disposed over the inductor device in an array arrangement from a plan view of the internal RDL structure. In some embodiments, the first die further comprises: a plurality of substrate-through vias (TSVs) penetrating through the substrate to electrically connect the device layer and the second RDL structure; and a planarization layer encapsulating the substrate, the device layer, the inductor device, and the inductor contact to contact a bottom surface of the internal RDL structure. In some embodiments, the internal RDL structure is configured to redistribute a current from the inductor contact to the plurality of conductive connectors. In some embodiments, the interposer further comprises: a second die arranged parallel to the first die; a plurality of insulator-through vias (TIVs) laterally surrounding the first die and the second die; and a first encapsulant laterally encapsulating the first die, the second die, and the plurality of TIVs. In some embodiments, the interposer further comprises: a second die vertically stacked over the first die to form a die stack structure; a plurality of insulator-through vias (TIVs) laterally surrounding the die stack structure; and a first encapsulant laterally encapsulating the die stack structure and the plurality of TIVs. In some embodiments, the package structure further includes: one or more package components disposed over the first RDL structure; a second encapsulant laterally encapsulating the one or more package components; a plurality of conductive terminals disposed on the second RDL structure; and a package substrate bonded to the interposer through the plurality of conductive terminals.

According to some embodiments, a package structure includes an interposer including a first package component sandwiched between a first RDL structure and a second RDL structure. The first package component includes: a bottom die; an inductor device, an active device die, and a passive device die arranged in parallel on the bottom die; an internal RDL structure disposed on the inductor device, the active device die, and the passive device die; and a plurality of conductive connectors disposed on the internal RDL structure to electrically connect the internal RDL structure and the first RDL structure.

In some embodiments, the first package component further comprises: an inductor contact disposed aside the inductor device and vertically sandwiched between the bottom die and the internal RDL structure, wherein the internal RDL structure is configured to redistribute a current from the inductor contact to the plurality of conductive connectors. In some embodiments, the bottom die comprises: a substrate; a device layer disposed on the substrate; a plurality of substrate-through vias (TSVs) penetrating through the substrate to electrically connect the device layer and the second RDL structure. In some embodiments, the interposer further comprises: a plurality of insulator-through vias (TIVs) laterally surrounding the first package component; and a first encapsulant laterally encapsulating the first package component and the plurality of TIVs. In some embodiments, the package structure further includes: one or more second package components disposed over the first RDL structure; a second encapsulant laterally encapsulating the one or more second package components; a plurality of conductive terminals disposed on the second RDL structure; and a package substrate bonded to the interposer through the plurality of conductive terminals. In some embodiments, the inductor device comprises: a coil structure and a magnetic material wrapping the coil structure.

According to some embodiments, a method of forming a package structure including: forming a first die on a first RDL structure; forming a second RDL structure on the first die to form an interposer; and forming a plurality of conductive terminals on the second RDL structure. The first die includes: a device layer formed on a substrate; an inductor device formed on the device layer; an internal RDL structure formed on the inductor device; a plurality of conductive connectors formed on the internal RDL structure; and an inductor contact formed aside the inductor device and electrically connecting the internal RDL structure and the inductor device, wherein the internal RDL structure is configured to redistribute a current from the inductor contact to the plurality of conductive connectors.

In some embodiments, the forming the interposer further comprises: arranging a second die parallel to the first die; forming a plurality of insulator-through vias (TIVs) to laterally surround the first die and the second die; and forming a first encapsulant to laterally encapsulate the first die, the second die, and the plurality of TIVs. In some embodiments, the forming the interposer further comprises: stacking a second die vertically over the first die to form a die stack structure; forming a plurality of insulator-through vias (TIVs) to laterally surround the die stack structure; and forming a first encapsulant to laterally encapsulate the die stack structure and the plurality of TIVs. In some embodiments, the method further includes: forming one or more package components over the first RDL structure; and forming a second encapsulant to laterally encapsulate the one or more package components.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
an interposer including a first die sandwiched between a first redistribution layer (RDL) structure and a second RDL structure, wherein the first die comprises:
a device layer disposed on a substrate;
an inductor device disposed on the device layer;
an internal RDL structure disposed on the inductor device;
a plurality of conductive connectors disposed on the internal RDL structure; and
an inductor contact disposed aside the inductor device and electrically connecting the internal RDL structure and the inductor device.

2. The package structure of claim 1, wherein the internal RDL structure has a conductive feature across the inductor device.

3. The package structure of claim 1, wherein a conductive feature of the internal RDL structure laterally surrounds the inductor device in a circular arrangement, so that the conductive feature of the internal RDL structure is not disposed directly over the inductor device.

4. The package structure of claim 1, wherein the plurality of conductive connectors laterally surround the inductor device in a circular arrangement from a plan view of the internal RDL structure.

5. The package structure of claim 1, wherein the plurality of conductive connectors are disposed over the inductor device in an array arrangement from a plan view of the internal RDL structure.

6. The package structure of claim 1, wherein the first die further comprises:
a plurality of substrate-through vias (TSVs) penetrating through the substrate to electrically connect the device layer and the second RDL structure; and
a planarization layer encapsulating the substrate, the device layer, the inductor device, and the inductor contact to contact a bottom surface of the internal RDL structure.

7. The package structure of claim 1, wherein the internal RDL structure is configured to redistribute an electrical signal from the inductor contact to the plurality of conductive connectors, and the number of the plurality of conductive connectors is greater than the number of the inductor contact.

8. The package structure of claim 1, wherein the interposer further comprises:
a second die arranged parallel to the first die;
a plurality of insulator-through vias (TIVs) laterally surrounding the first die and the second die; and
a first encapsulant laterally encapsulating the first die, the second die, and the plurality of TIVs.

9. The package structure of claim 1, wherein the interposer further comprises:
a second die vertically stacked over the first die to form a die stack structure;
a plurality of insulator-through vias (TIVs) laterally surrounding the die stack structure; and
a first encapsulant laterally encapsulating the die stack structure and the plurality of TIVs.

10. The package structure of claim 1, further comprising:
one or more package components disposed over the first RDL structure;
a second encapsulant laterally encapsulating the one or more package components;
a plurality of conductive terminals disposed on the second RDL structure; and
a package substrate bonded to the interposer through the plurality of conductive terminals.

11. A package structure, comprising:
an interposer including a first package component sandwiched between a first RDL structure and a second RDL structure, wherein the first package component comprises:
a bottom die;
an inductor device, an active device die, and a passive device die arranged side by side on the bottom die;
an internal RDL structure disposed on the inductor device, the active device die, and the passive device die; and
a plurality of conductive connectors disposed on the internal RDL structure to electrically connect the internal RDL structure and the first RDL structure.

12. The package structure of claim 11, wherein the first package component further comprises:
an inductor contact disposed aside the inductor device and vertically sandwiched between the bottom die and the internal RDL structure, wherein the internal RDL structure is configured to redistribute an electrical signal from the inductor contact to the plurality of conductive connectors.

13. The package structure of claim 11, wherein the bottom die comprises:
a substrate;
a device layer disposed on the substrate;
a plurality of substrate-through vias (TSVs) penetrating through the substrate to electrically connect the device layer and the second RDL structure.

14. The package structure of claim 11, wherein the interposer further comprises:
a plurality of insulator-through vias (TIVs) laterally surrounding the first package component; and
a first encapsulant laterally encapsulating the first package component and the plurality of TIVs.

15. The package structure of claim 11, further comprising:
one or more second package components disposed over the first RDL structure;
a second encapsulant laterally encapsulating the one or more second package components;
a plurality of conductive terminals disposed on the second RDL structure; and
a package substrate bonded to the interposer through the plurality of conductive terminals.

16. The package structure of claim 11, wherein the inductor device comprises: a coil structure and a magnetic material wrapping the coil structure.

17. A method of forming a package structure, comprising:
forming a first die on a first RDL structure;
forming a second RDL structure on the first die to form an interposer; and
forming a plurality of conductive terminals on the second RDL structure, wherein the first die comprises:
a device layer formed on a substrate;
an inductor device formed on the device layer;
an internal RDL structure formed on the inductor device;
a plurality of conductive connectors formed on the internal RDL structure; and
an inductor contact formed aside the inductor device and electrically connecting the internal RDL structure and the inductor device, wherein the internal RDL structure is configured to redistribute an electrical signal from the inductor contact to the plurality of conductive connectors.

18. The method of forming the package structure of claim 17, wherein the forming the interposer further comprises:
arranging a second die parallel to the first die;
forming a plurality of insulator-through vias (TIVs) to laterally surround the first die and the second die; and
forming a first encapsulant to laterally encapsulate the first die, the second die, and the plurality of TIVs.

19. The method of forming the package structure of claim 17, wherein the forming the interposer further comprises:
stacking a second die vertically over the first die to form a die stack structure;
forming a plurality of insulator-through vias (TIVs) to laterally surround the die stack structure; and
forming a first encapsulant to laterally encapsulate the die stack structure and the plurality of TIVs.

20. The method of forming the package structure of claim 17, further comprising:
forming one or more package components over the first RDL structure; and
forming a second encapsulant to laterally encapsulate the one or more package components.
